(19) United States
(12) Patent Application Publication
(10) Pub. No.: US 2001/0036735 A1
(43) Pub. Date: Nov. 1, 2001

(54) Semiconductor device adapted for polishing

(76) Inventor: Robert L. Rhoades, Phoenix, AZ (US)

Correspondence Address: Rodel Holdings, Inc., Suite 1300, 1105 North Market Street, Wilmington, DE, 19899, US

(21) Appl. No.: 09/815,091

(22) Filed: Mar. 22, 2001

Related U.S. Application Data
(60) Provisional application No. 60/191,573, filed on Mar. 23, 2000.

(51) Int. Cl. H01L 21/302; H01L 21/461; H01L 23/48

(52) U.S. Cl. 438/690; 438/692; 257/752

(57) ABSTRACT

A semiconductor device is adapted for polishing with a slurry having a selectivity for removing a material from a stop layer on the semiconductor device, and the semiconductor device is polished with the slurry to remove the material, and to expose sulfur on the stop layer, and the sulfur chemically reacts with the slurry to reduce the selectivity for removing the material, which slows removal of the material by continued polishing.

### CROSS REFERENCE TO RELATED APPLICATION

This application claims the benefit of provisional application Ser. No. 60/191,573, filed Mar. 23, 2000.

### BACKGROUND OF THE INVENTION

1. Field of the Invention

The invention relates to a semiconductor device adapted for polishing by chemical mechanical planarization, CMP.

2. Discussion of Related Art

A known semiconductor device with shallow trench isolation is fabricated by depositing a stop layer of silicon nitride onto a silicon substrate, followed by performing a photoetching process that form trenches in both the stop layer and the silicon substrate, in turn, followed by depositing a silicon dioxide dielectric material, such that the trenches become filled with the silicon dioxide. Further, the silicon dioxide forms a layer that needs to be removed. A process of polishing by CMP is performed, which removes the layer of silicon dioxide while leaving the silicon dioxide in the filled trenches. The filled trenches provide what is known as, shallow trench isolation features. Such features serve to separate and electrically isolate integrated circuit elements that are constructed on the semiconductor device.

Polishing by CMP removes the layer of silicon dioxide, which exposes the stop layer. An exposed stop layer is an indication that the silicon dioxide has been completely removed by polishing, and that such polishing should be stopped. A condition known as underpolishing refers to a polishing operation that has been stopped too soon, which causes spots of the silicon dioxide to remain and cover portions of the stop layer. A condition known as overpolishing refers to a polishing operation that has continued for too long a time duration, which results in the filled trenches being polished excessively, to become concave, and thereby, to become indicative of an undesired polishing result known as dishing.

Rapid removal of the layer of silicon dioxide is desired, to achieve a high rate of production of polished semiconductor devices. However, when rapid removal is being accomplished by polishing, the difference between the time duration for underpolishing and the time duration for overpolishing is shortened. Further, since the time duration for polishing is merely an approximation, such approximation increases the risks of overpolishing and underpolishing when the time duration expires and the polishing operation stops. In the past, the risks of overpolishing and underpolishing were minimized by slowing the polishing operation to lower the rate at which material was removed, as the layer of silicon dioxide became thinner, which undesirably slowed the rate of production.

### SUMMARY OF THE INVENTION

The invention minimizes the risks of overpolishing and underpolishing by a polishing operation that rapidly removes material from a semiconductor device. According to the invention, a semiconductor device is adapted for polishing with a slurry that is selective to remove a material from the semiconductor device, the semiconductor device having a stop layer to become exposed by removal of the material from the semiconductor device, and a surface on the stop layer having sulfur thereon that becomes exposed and chemically reacts with the slurry to slow further removal of the material by such polishing, which minimizes risks of overpolishing and underpolishing when such polishing stops. The terminology “slurry” is intended to apply to a fluid polishing composition that either contains abrasives or that is free of abrasives.

Further, the invention is directed to a method of making a semiconductor device adapted for polishing with a slurry having a selectivity for removing a material from a stop layer on the semiconductor device, comprising the steps of: depositing a substance on the stop layer, such substance being chemically reactive with the slurry to reduce the selectivity, and covering the substance on the stop layer with the material to be removed by polishing with the slurry.

Embodiments of the invention will now be described by way of example with reference to the following detailed description.

### DETAILED DESCRIPTION

The invention is directed to the technical field of polishing a semiconductor device, for example, a semiconductor device on which various active and passive integrated circuit elements must be electrically isolated from one another while on the semiconductor device, such as, a semiconductor wafer of silicon. Such isolation is provided in part by shallow trench isolation, according to which silicon dioxide (silica) is a dielectric material in trenches, and silicon nitride provides a nitride layer or stop layer.

In addition to the dielectric material that fills the trenches, a further amount of such dielectric material is in the form of a layer that needs to be removed by polishing with a slurry having a chemistry that is selective to remove silica. For example, the slurry provides a higher removal rate selectivity for silica than for silicon nitride. Silvestri et al., U.S. Pat. No. 4,526,631, discloses a slurry having a polishing ratio of about 10 SiO₂ to 1 Si₃N₄. Beyer et al., U.S. Pat. No. 4,671,851, discloses polishing ratios (between SiO₂ and Si₃N₄) between a lower limit of 4 to 1 and a higher limit of 40 to 1. U.S. Pat. No. 5,502,007 to Murase, discloses selectivities of about 10 SiO₂ to 1 Si₃N₄. Kodera et al., U.S. Pat. No. 5,445,996, discloses selectivities for SiO₂ to Si₃N₄ removal rates in the range of 2 to 3. Hosali et al., U.S. Pat. No. 5,378,800 discloses selectivities as high as 296 SiO₂ to 1 Si₃N₄.

Polishing by CMP removes the layer of silicon dioxide, which exposes the stop layer. An exposed stop layer is an indication that the silicon dioxide has been completely removed by polishing, and that such polishing should be stopped. To automate the polishing operation, a time duration is chosen for performing the polishing operation. The time duration for polishing is chosen to expire with a coincident occurrence of complete removal of the silicon dioxide from the stop layer. However, the chosen time duration is merely an approximation, due to variations that are expected to occur during a polishing operation, and because semiconductor devices that would appear to be similar need to be polished for different lengths of time. A condition known as underpolishing refers to a polishing operation that has been stopped too soon, which causes spots of the silicon dioxide to remain and cover portions of the stop layer. A condition known as overpolishing refers to a polishing operation that has continued for too long a time duration, which results in the filled trenches being polished excessively, to become concave, and thereby, indicative of an undesired polishing result known as dishing.

A common practice is to observe how much material is removed by polishing for a measured time duration, which provides a removal rate of the material for a particular polishing pad/slurry combination. A typical pad/slurry combination is IC1000 and Klebosol 30S25, both sold by Rodel, Inc of Newark, Del. Inherent variability in the process and products being polished leads to merely an approximation of the polishing time duration needed for completely removing a layer of material. Such an approximation can result in overpolishing the silicon dioxide causing dishing. Alternatively, such an approximation can result in underpolishing the silicon dioxide and not fully exposing the nitride layer or stop layer.

According to the invention, sulfur is present at a surface of the nitride layer or stop layer. The sulfur becomes exposed when the polishing operation has removed at least some of the layer of silicon dioxide from the nitride layer. Further, the sulfur becomes exposed to the slurry and will chemically react with the slurry to reduce the removal rate selectivity of the slurry for the silicon dioxide, which substantially reduces the rate at which the silicon dioxide is removed as the polishing operation continues. The risks of overpolishing and underpolishing are minimized, because the rate of removal of the layer of silicon dioxide slows further as more of the layer becomes removed to expose more sulfur. Further, the rate of removal of the silicon dioxide slows without having to slow the polishing operation, which maintains a high production rate of polished semiconductor devices.

According to the invention, sulfur on a surface of the semiconductor device reacts chemically with the slurry, slowing removal of the silicon dioxide as polishing continues. Further, according to the invention, sulfur, as referred to herein, is meant to include, and is not limited to, elemental sulfur, and a chemical compound of sulfur, and both elemental sulfur and a chemical compound of sulfur. Such a chemical compound of sulfur includes, and is not limited to, sulfur oxide and sulfur nitride.

Further, according to the invention, a semiconductor device has sulfur present on the surface of the stop layer. Accordingly, the silicon dioxide is removed rapidly by polishing until such polishing exposes the sulfur, which causes the removal of silicon dioxide to slow further as more sulfur becomes exposed by polishing. Thus, the risks of overpolishing and underpolishing are minimized, without having to slow the polishing operation.

Further, the invention is directed to incorporation of sulfur into or onto a stop layer such as, silicon nitride. By selectively doping, depositing or coating the nitride layer or stop layer with sulfur, the sulfur is exposed at the same time the nitride layer or stop layer is exposed.

A method of providing sulfur on a surface of a nitride layer or stop layer includes, and is not limited to, adding sulfur dopants to the gaseous mixture in a nitride deposition applied by a furnace or by a chemical vapor deposition CVD chamber, ion implantation of sulphur ions into the nitride film after deposition thereof onto the silicon substrate, exposing the deposited nitride film to sulfur-containing gas, and coating the nitride layer or stop layer with a sulfur-containing liquid or solid. Another method includes exposing the deposited nitride layer or stop layer to a sulfur-containing gas at reduced atmosphere and at elevated temperatures, which is an annealing process.

Embodiments of the invention having been disclosed, other embodiments and modifications of the invention are intended to be covered by the spirit and scope of the appended claims.

What is claimed is:

1. A semiconductor device adapted for polishing with a slurry having a selectivity to remove a material from the semiconductor device, the semiconductor device comprising: a stop layer to become exposed by removal of the material from the semiconductor device, and a surface on the stop layer having sulfur thereon that becomes exposed and chemically reacts with the slurry to slow further removal of the material by such polishing, which minimizes risks of overpolishing and underpolishing when such polishing stops.

2. The semiconductor device as recited in claim 1 wherein the sulfur is elemental sulfur or a chemical compound of sulfur, or is both elemental sulfur and a chemical compound of sulfur.

3. The semiconductor device as recited in claim 1 wherein the stop layer is silicon nitride.

4. The semiconductor device as recited in claim 1 wherein the top layer is under a layer of the material.

5. A method of polishing a semiconductor device that is adapted for polishing with a slurry having a selectivity for removing a material from a stop layer on the semiconductor device, comprising the steps of:
polishing the semiconductor device with the slurry to remove the material, and to expose sulfur on the stop layer,
chemically reacting the sulphur with the slurry to reduce the selectivity for removing the material, which slows removal of the material without having to slow the polishing, and
stopping the polishing upon expiration of a chosen time duration.

6. A method of polishing a semiconductor device that is adapted for polishing with a slurry having a selectivity for removing a material from a stop layer on the semiconductor device, comprising the steps of:
polishing the semiconductor device with the slurry to remove the material, and to expose sulfur on the stop layer,
chemically reacting the sulphur with the slurry to reduce the selectivity for removing the material, which reduces risks of overpolishing and underpolishing when the polishing stops, and
stopping the polishing upon expiration of a chosen time duration.

7. A method of making a semiconductor device adapted for polishing with a slurry having a selectivity for removing a material from a stop layer on the semiconductor device, comprising the steps of:
depositing a substance on the stop layer, such substance being chemically reactive with the slurry to reduce the selectivity, and
covering the substance on the stop layer with the material to be removed by polishing with the slurry.

8. The method as recited in claim 7 wherein the step of depositing the substance on the top layer, further comprises the step of, depositing the substance as sulfur.

9. The method as recited in claim 7 wherein the step of depositing the substance on the top layer, further comprises the step of, depositing the substance as elemental sulfur or as a chemical compound of sulfur, or as both elemental sulfur and a chemical compound of sulfur.
